(19) United States
(12) Patent Application Publication
(10) Pub. No.: US 2002/0049943 A1
(43) Pub. Date: Apr. 25, 2002

(54) Semiconductor test system

(76) Inventor: Shinichi Kobayashi, Kumagaya-shi (JP)

Correspondence Address: MURAMATSU & ASSOCIATES, Suite 225, 7700 Irvine Center Drive, Irvine, CA, 92618, US

(21) Appl. No.: 09/941,394

(22) Filed: Aug. 28, 2001

(30) Foreign Application Priority Data
Aug. 28, 2000 (JP) 2000-263242

(51) Int. Cl. G06F 11/00; G01R 31/28

(52) U.S. Cl. 714/734; 714/738

(57) ABSTRACT

A semiconductor test system for testing a semiconductor device by applying a test pattern to a device under test. The semiconductor test system is capable of generating test patterns based on predetermined algorithmic sequences and/or inverting data pattern in the test pattern based on predetermined algorithmic sequences. The semiconductor test system is capable of utilizing the same pattern program for different test items, thereby enabling to decrease the required capacity in an instruction memory. Especially, generation of inversion control signal can be made by using the same pattern program without increasing the capacity of the instruction memory.

### FIELD OF THE INVENTION

This invention relates to a semiconductor test system for testing semiconductor devices, and more particularly, to a semiconductor test system having an algorithmic pattern generator which is capable of generating test patterns based on predetermined algorithmic sequences and/or inverting data in the test pattern based on predetermined algorithmic sequences for testing semiconductor devices.

### BACKGROUND OF THE INVENTION

In testing semiconductor devices such as ICs and LSIs by a semiconductor test system, a semiconductor IC device to be tested is provided with test signals (test patterns) produced by a pattern generator in the semiconductor test system at its appropriate test pins at predetermined test timings. The IC device under test produces output signals in response to the test signals which are received by the semiconductor test system. The output signals are strobed (sampled) by strobe signals at predetermined timings to be compared with expected value data to determine whether the IC device functions correctly or not.

In the case where a device under test (DUT) is a semiconductor memory, the test pattern applied to the DUT consists of address data, write data, and control data. After writing predetermined data in predetermined addresses (memory cells) of the DUT, the data in the addresses is read to determine whether the stored data in the memory is the same as the write data. For testing a semiconductor memory, a test pattern generated by the pattern generator includes various data and control signals including the address data, write data and control data noted above as well as expected data, address and control data for a failure memory to store the test results therein.

An example of basic structure of a semiconductor test system is shown in a block diagram of FIG. 1. In this example, the semiconductor test system includes a timing generator TG for generating timing clocks (ACLK, BCLK, CCLK), a pattern generator PG for generating a test pattern including an address pattern (APAT), a data pattern (DPAT) and a control pattern (CPAT), a programmable data selector (PDS) for selecting the test pattern, and a format controller (wave formatter) FC for wave shaping the test pattern. The test system further includes a driver DR for supplying the test pattern to the DUT, a digital (logic) comparator DC for comparing an output signal (data) of the DUT with expected value data (EXP22) at the timing of strobe signals (STB3), and an address fail memory AFM for storing test results for later failure analysis.

Upon detecting a mismatch between the DUT output data and the expected value data EXP22, error indication is produced by the comparator DC. Such error (failure) data is stored in the address fail memory AFM in the addresses specified by the address data from the pattern generator PG which corresponds to the addresses of the DUT. The error data in the address fail memory AFM may represent the actual value of the device output pin at the strobe point, or it can be just a single bit of data indicating pass or fail. The test engineers and design engineers use the error data in the address failure memory AFM to analyze correctness of the device design and functions.

As is well known in the art, a memory is configured by a large number of memory cells each being specified by a combination of a row (X) address and a column (Y) address. In memory testing, one of the important test items is to examine whether there is an interference between memory cells, which is sometimes called “pattern sensitive faults” or “neighborhood pattern sensitive faults”. Typically, such a fault is examined by using a test pattern having an algorithmic sequence, such as a marching pattern, checker board pattern, and the like.

Especially, such pattern sensitive faults are effectively detected by writing data (such as “1”) in a particular memory cell which is opposite to data (such as “0”) in adjacent memory cells. The semiconductor test system monitors whether the particular cell correctly stores the write data “1” when all the neighborhood cells store the write data “0”. In other words, a pattern generator in the semiconductor test system is so designed that it can invert write data for a specified memory cell (address) of the memory device under test.

To generate such complicated test patterns, the pattern generator PG includes an algorithmic pattern generator (ALPG) which has an algorithmic function therein for generating test patterns with sequences of mathematical algorithm and for inverting data for particular addresses of the memory under test. Because of such a data inversion function provided in the pattern generator, a complicated test pattern can be generated at high speed without requiring a complicated test pattern program.

An example of basic structure in the ALPG is shown in the block diagram of FIG. 2. In this example, the pattern generator PG (or ALPG) is comprised of a sequence controller 500, an address generator 100, a data generator 200, and a control signal generator 300. As shown in FIG. 1, the pattern generator PG (ALPG) receives the timing (reference) clocks from the timing generator TG, thereby generating the test pattern (address data, write data, and control signals, etc.) in synchronism with the reference clock. Typically, the contents of the test pattern is unique to a particular device under test (DUT).

The sequence controller 500 includes an instruction memory WCS having a capacity of several kilo words for storing pattern programs, a program counter PC, and a pattern counter controller PCCNT. The program counter PC operates at a test rate and sequentially supplies the address data to the instruction memory WCS. The program counter controller PCCNT controls the address generation by the program counter PC based on the instructions from the instruction memory WCS.

In the instruction memory WCS, a group of pattern instructions in a predetermined description format are stored which are created and translated based on the pattern programs described in a predetermined manner. Among this group of pattern commands, an address operation command ACMD1 is supplied to the address generator 100, a data operation command DCMD2 is supplied to the data generator 200, and a control signal operation command CCMD3 is supplied to the control signal generator 300, where all commands are supplied in parallel at the same time.

The address generator 100 generates an address pattern in the test pattern. For example, the address generator 100 generates a complicated address pattern APAT with 32-bit width configured by a 16-bit row address RA and a 16-bit column address CA. The address generator 100 is provided with a dedicated arithmetic circuit therein which produces the address pattern APAT with a row address RA and a column address CA upon receiving the address operation command ACMD1 from the instruction memory WCS for testing a memory device. This address pattern APAT is also supplied to the data generator 200 to execute a predetermined logic operations for generating inversion signals.

The data generator 200 generates write data and expected value data in the test pattern. The write data is to write the memory device under test and the expected valued data is to compare the data read from the memory device under test. The data generator 200 is provided with a dedicated arithmetic circuit therein which produces a complicated data pattern DPAT upon receiving the data operation command DCMD2 from the instruction memory WCS and the address pattern APAT from the address generator 100 for testing the memory device. The data pattern DPAT has a data width of, for example, 36-bit.

The control signal generator 300 generates control signal patterns CPAT which are mainly supplied to the memory device under test. An example of the control signal pattern includes chip enable (CE), write enable (WE), output enable (OE), row address strobe (RAS) and column address strobe (CAS), which are supplied to corresponding pins of the memory device under test.

FIG. 4 shows an example of structure in the data generator 200. In this example, the data generator 200 includes an inversion signal generator 60, a data arithmetic circuit 50, and a data inversion circuit 90. As an example of internal structure, the inversion signal generator 60 is formed of a checker board inversion signal generator 62, a diagonal inversion signal generator 64, an inverted checker board inversion signal generator 66, a non-inversion signal generator 68, and a selector (multiplexer) 70.

The checker board inversion signal generator 62 receives the address pattern APAT and generates a first inversion signal 62s when a predetermined logic operation on the address data indicates to generate a checker board test pattern.

FIG. 3 (a) shows an example of checker board test pattern where logic “0” and “1” are arranged in a checker board fashion. This is a simple example consisting of a 2-bit row address RA and a 2-bit column address CA. The data value “1” in FIG. 3 indicates that the inversion condition is valid. To generated the checker board test pattern such as shown in FIG. 3 (a), the checker board inversion signal generator 62 outputs the first inversion signal 62s for inverting the data pattern DPAT. As shown in FIG. 4, the first inversion signal 62s is generated every time when an exclusive OR (XOR) operation between the lowest bit (RAO) of the row address RA and the lowest bit (CAO) of the column address CA indicates “1”, i.e., CAO.eor.RAO=1.

The diagonal inversion signal generator 64 shown in FIG. 4 receives the address pattern APAT and generates a second inversion signal 64s when a predetermined logic operation on the address data indicates to generate a diagonal test pattern.

FIG. 3(b) shows an example of diagonal test pattern where a direction of logic “1” is diagonally arranged therein in memory cells. To generated the diagonal test pattern such as shown in FIG. 3(b), the diagonal inversion signal generator 64 outputs the second inversion signal 64s for inverting the data pattern DPAT. As shown in FIG. 4, the second inversion signal 64s is generated every time when the sum of the row address RA and a value specifying a position of the diagonal line (DIASL) is equal to the column address CA, i.e., RA+DIASL=CA.

The inverted diagonal inversion signal generator 66 shown in FIG. 4 receives the address pattern APAT and generates a third inversion signal 66s when a predetermined logic operation on the address data indicates to generate an inverted diagonal test pattern.

FIG. 3(c) shows an example of inverted diagonal test pattern where a direction of logic “1” is opposite to that of the example of FIG. 3(b). To generated the diagonal test pattern such as shown in FIG. 3(c), the diagonal inversion signal generator 64 outputs the third inversion signal 66s for inverting the data pattern DPAT. In this case, as shown in FIG. 4, the third inversion signal 66s is generated every time when the inverted sum of the row address RA and the value specifying a position of the diagonal line (DIASL) is equal to the column address CA, i.e., \overline{RA+DIASL}=CA.

The non-inversion signal generator 68 shown in FIG. 4 regularly outputs a non-inversion signal FIXL which indicates logic “0”. The non-inversion signal FIXL is used when the output data of the data arithmetic circuit 50 is desired to be used as data pattern DPAT without including any inversion.

An example of the selector 70 in FIG. 4 is a multiplexer formed of four inputs and one output. The selector 70 receives the three inversion signals 62s, 64s, 66s and one non-inversion signal FIXL, and selects one of the signals based on an inversion control signal INVSL. For example, the inversion control signal INVSL is configured by a plurality of bits and included in the data operation command DCMD2 from the sequence controller 500 (instruction memory WCS). The inversion signal 70s selected by the selector 70 is provided to the data inversion circuit 90.

The data arithmetic circuit 50 has a dedicated arithmetic unit therein for performing an arithmetic function. The data arithmetic circuit 50 receives the data operation command DCMD2 consisting of a plurality of bits from the sequence controller 500. Based on the data operation command DCMD2, the data arithmetic circuit 50 generates a data pattern 50s with, for example, a 36-bit width, to be used either as the write data for a memory under test or as the expected value data.

The data inversion circuit 90 receives the 36-bit width data pattern 50s, and when the inversion signal 70s, which is, for example, one bit signal from the selector 70, is valid (assert), it outputs the data pattern DPAT where each of the 36-bit data is inverted in the logic.

The schematic diagram of FIG. 5 shows a manner of data storage in the instruction memory WCS when storing the device test program. The device test program is formed with a main program and a pattern program. The main program is stored in a memory of system controller CPU. The main program is used to set or change various test conditions for the memory device under test (such as amplitudes of test patterns by the drivers, and threshold levels for the comparators, etc.), to control start/stop of the pattern program, and to conduct the test result analysis process of the test results. The data regarding the various test conditions mentioned above are transferred to the corresponding blocks in the test system through the tester bus TBUS (FIG. 1).

The pattern program is to generate a test pattern from a predetermined start address for each test item. An example of such test items includes various functional tests, AC parametric tests, and DC parametric tests. For each test item, the corresponding pattern program is loaded in the test system before starting the test item. The pattern data for the program counter controller PCCNT, and for generating the address pattern APAT, the data pattern DPAT, and the control signal pattern CPAT is produced by translating the description in the pattern program, and is stored in the instruction memory WCS.

Then, upon receiving an activation instruction from the main program, the pattern generation will begin from the designated start address for each test item. Eventually, the operational control is returned to the main program when a generation end command described in the test pattern being generated.

In FIG. 5, it is assumed that the contents of pattern data in the address operation command ACMD1, data operation command DCMD2, and control signal operation command CCMD3 are the same in the respective memory areas A, B, C, and D except for the contents of the inversion control signal INVSL in the memory areas F. In addition, it is assumed that the symbols FP0, FP1, FP2, and FP3 in the inversion control signal INVSL are mnemonics indicating specific types of inversion mode. For example, the mnemonic FP0 denotes a non-inversion mode, the mnemonic FP1 denotes a checker board inversion mode, the mnemonic FP2 denotes a diagonal inversion mode, and the mnemonic FP3 denotes an inverted diagonal inversion mode, respectively.

It is further assumed that, for the test pattern in the memory area A, the inversion mode is limited to the checker board inversion mode FP1 or a combination of the non-inversion mode FP0 and the checker board inversion mode FP1, and for the test pattern in the memory area B, the inversion mode is limited to the diagonal inversion mode FP2 or a combination of the non-inversion mode FP0 and the diagonal inversion FP2. Similarly, for the test pattern in the memory area C, the inversion mode is limited to the inverted diagonal inversion mode FP3 or a combination of the non-inversion mode FP0 and the inverted diagonal inversion mode FP3, and for the test pattern in the memory area D, the inversion mode is limited to the non-inversion mode FP0.

Moreover, in FIG. 5, each of the data in the memory areas A, B, C, and D is a unit of pattern program corresponding to intended test item. For example, the memory area A stores the pattern program for a functional test, the memory area B stores the pattern program for a DC parametric test, and the like. Such units of pattern program are sequentially called from the main program as shown in FIG. 5. Each pattern program is executed starting from the first address and ending at the last address and is returned to the main program.

In the above situation, even when the pattern programs are identical to one another, each pattern program “ACMD1 DCMD2 CCMD3” is separately stored in the memory areas A, B, C, and D because the inversion control signals INVSL are different from one another. As a result of having to store the test patterns separately, an overall storage area that is four times larger than the actual unit of pattern program is required in the instruction memory WCS.

Therefore, the method of storing the pattern data shown in FIG. 5 is not an effective way to fully use or save the available memory capacity. Thus, when the memory under test is a complicated one, requiring a lengthy and complicated test pattern, the capacity of the instruction memory WCS may become insufficient, which may also require the pattern programs be further divided.

Further in FIG. 5, it is necessary to produce a plurality of identical pattern programs each having a different condition of the inversion control. Thus, it requires a large number of pattern programs and a large capacity of storage medium to store such pattern programs. Moreover, it increases administrative work for managing and maintaining the associated source files and object files.

As described in the foregoing, the algorithmic pattern generator ALPG in the conventional technology involves an ineffective way of using the memory capacity. For example, the conventional technology requires to store a plurality of identical pattern programs where only the inversion conditions in the inversion control signal INVSL are different.

Generally, the storage capacity of the ALPG is relatively small such as several kilo words. Thus, in the case where a complicated memory device has to be tested which requires a lengthy and complicated test pattern, the storage capacity of the ALPG may become insufficient. Thus, it is required to divide the pattern programs to be loaded in the instruction memory WCS, resulting in decrease in device test efficiency and device throughput. From these points, the method of storing the data inversion control function in the conventional ALPG has drawbacks in the practical use.

### SUMMARY OF THE INVENTION

Therefore, it is an object of the present invention is to provide a semiconductor test system having an algorithmic pattern generator which is able to effectively utilize storage capacity of an instruction memory in the algorithmic pattern generator.

It is another object of the present invention to provide a semiconductor test system having an algorithmic pattern generator which is capable of generating test patterns for testing a complicated memory device without increasing a memory capacity of the instruction memory in the algorithmic pattern generator.

It is a further object of the present invention to provide a semiconductor test system having an algorithmic pattern generator in which control signals associated with the common pattern program are arranged outside of an instruction memory.

It is a further object of the present invention to provide a semiconductor test system having an algorithmic pattern generator in which pattern components associated with the common pattern program are separated from the pattern program and are freely assigned to the pattern program through the specific circuit arrangement.

The semiconductor test system for testing semiconductor devices by applying a test pattern to a semiconductor device under test includes:

means for storing a main program for controlling an overall operation of the semiconductor test system where the main program including pattern programs for producing test patterns to be applied to a device under test;

an instruction memory for storing a pattern program and control mode data from the main program required for generating a test pattern for conducting an intended test item on the device under test;

means for generating a data pattern which is a part of the test pattern to be applied to the device under test and modifying the data pattern;

means for setting control mode data identical to that stored in the instruction memory in a temporary storage;

means for producing a modification signal based on the control mode data and providing the modification signal to the data pattern generating means to modify the data pattern; and

means for switching the control mode data either from the instruction memory or from the temporary storage for producing a selection control signal for controlling the modification signal producing means in generating the modification signal.

In the present invention, the temporary storage in the control mode data setting means is a register which receives the control mode data from the main program. The switching means includes a mode selection register which specifies either a first mode or a second mode wherein, in the first mode, the modification signal producing means is controlled based on the control mode data from the instruction memory, and in the second mode, the modification signal producing means is controlled based on the control mode data from the temporary storage.

In the present invention, the modification signal from the modification signal producing means is a signal indicating an inversion operation and is applied to a data inversion circuit for inverting the data from the data pattern generating means.

The modification signal producing means includes one or more inversion signal generators each generating an inversion signal based on a predetermined inversion algorithm, and a selector for selecting an inversion signal from one of the inversion signal generators to be used as said modification signal in response to said control mode data from either the instruction memory or from the temporary storage.

In the present invention, an example of the inversion algorithm includes a checker board inversion algorithm, a diagonal inversion algorithm, and an inverted diagonal algorithm wherein each algorithm by the inversion signal generator is performed with use of address data supplied to the semiconductor device under test.

According to the present invention, the pattern components such as inversion control signals associated with the common pattern program are separated from that pattern program and are freely specified and called, and are freely assigned to the pattern program through the specific circuit arrangement. Therefore, it is possible to utilize the same pattern program for different test items, thereby enabling to decrease the required capacity in the instruction memory in the pattern generator. Especially, the generation of various inversion data such as the checker board, diagonal, and inverted diagonal can be made by using the same pattern program without increasing the memory capacity.

### BRIEF DESCRIPTION OF THE DRAWINGS

FIG. 1 is a schematic diagram showing an example of basic structure in a semiconductor test system.

FIG. 2 is a schematic diagram showing an example of basic structure in an algorithmic pattern generator ALPG.

FIGS. 3(a), 3(b) and 3(c) respectively show data inversion in a checker board test pattern, a diagonal test pattern, and an inverted diagonal test pattern, with respect to memory cell locations.

FIG. 4 is a diagram showing an essential structure concerning a data inversion function in a data generator in the conventional algorithmic pattern generator ALPG.

FIG. 5 is a diagram explaining a relationship between the main program and the pattern program and a conventional method of storing the pattern program in the instruction memory received from the main program.

FIG. 6 is a diagram showing an essential structure concerning a data inversion function in the data generator in the algorithmic pattern generator ALPG of the present invention.

FIG. 7 is a diagram explaining a relationship between the main program and the pattern program and a method of storing the pattern program in the instruction memory received from the main program in the present invention.

### DETAILED DESCRIPTION OF THE INVENTION

Reference will now be made in detail to a preferred embodiment of the present invention, an example of which is illustrated in the accompanying drawings.

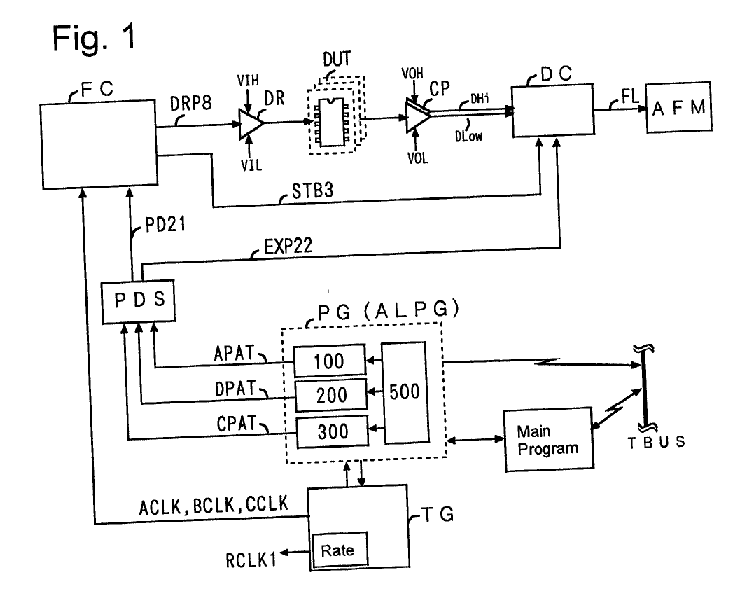

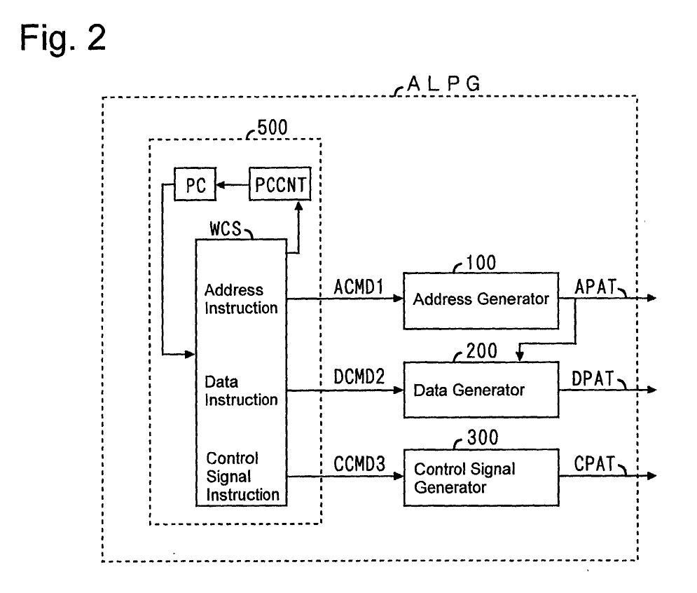

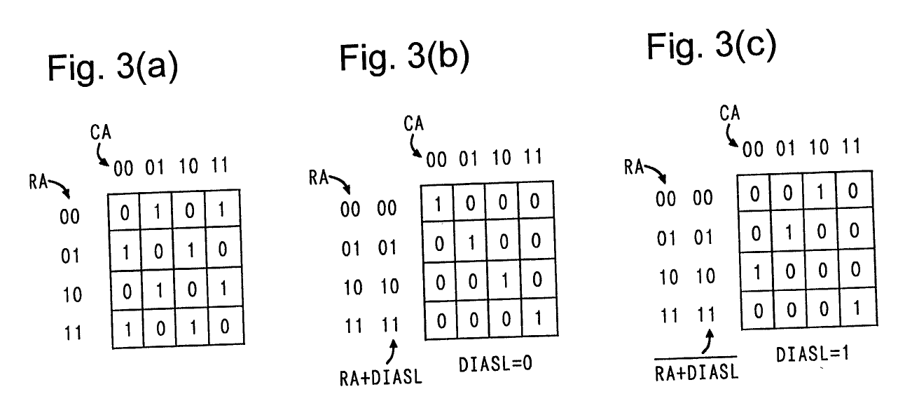

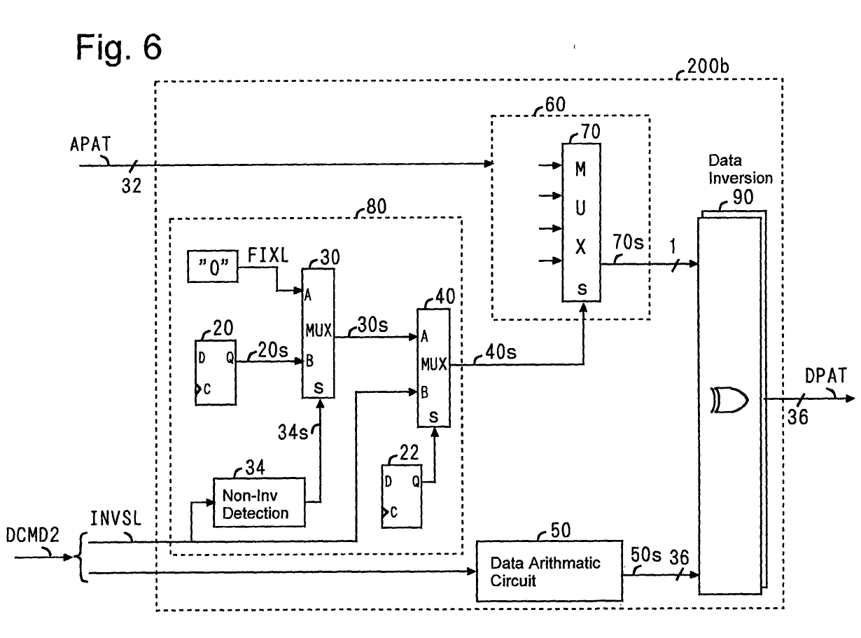

FIG. 6 shows a structure in a data generator 200b in the present invention concerning the data inversion function. As explained in the background of the invention with reference to FIGS. 1 and 2, the data generator 200b is a part of the algorithmic pattern generator ALPG incorporated in a semiconductor test system. The components identical to that of the conventional example of FIGS. 1-5 are denoted by the same reference numerals.

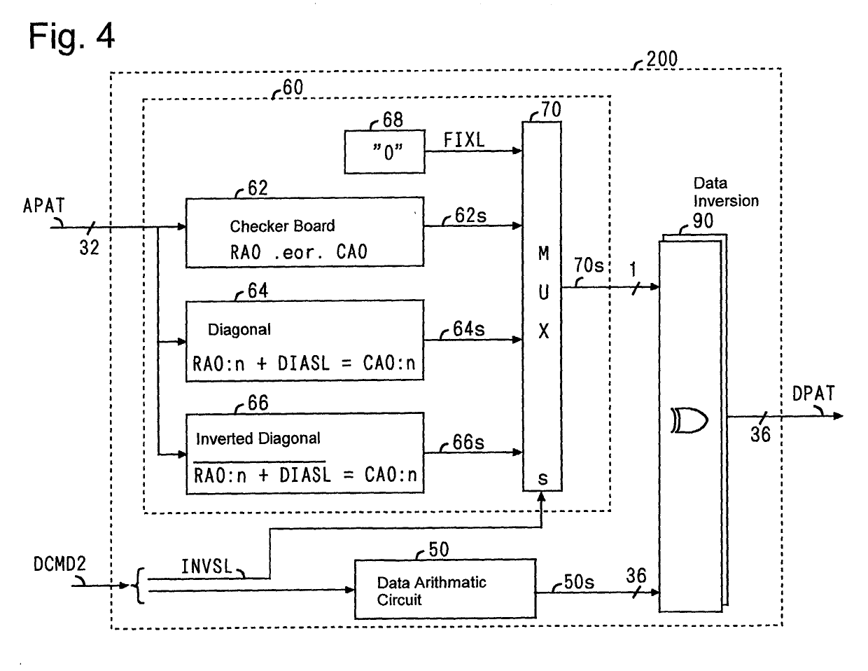

The data generator 200b of FIG. 6 includes an inversion signal generator 60, a data arithmetic circuit 50, and a data inversion circuit 90 which are basically the same as that shown in FIG. 4. Thus, although abbreviated, the inversion signal generator 60 is formed of the checker board inversion signal generator 62, the diagonal inversion signal generator 64, the inverted checker board inversion signal generator 66, the non-inversion signal generator 68, and the selector 70. The essential difference in the data generator 200b from the conventional data generator 200 in FIG. 4 is that the present invention includes an inversion control switch circuit 80.

Under either one of the traditional operation modes or a new operation mode, the inversion control switch circuit 80 receives an inversion control signal INVSL from the instruction memory WCS, and supplies an inversion control signal 40s generated under a predetermined condition to a selection control signal input of the selector (multiplexer MUX) 70 in the inversion signal generator 60.

An example of detailed structure in the inversion control switch circuit 80 is shown in FIG. 6, which includes a set register 20, a mode select register 22, a non-inversion detection circuit 34, a first multiplexer (MUX) 30, and a second multiplexer (MUX) 40.

The set register 20 is a register with, for example, a 2-bit length, and is able to change the settings through the tester bus TBUS at any time. Optional inversion mode set data 20s which corresponds to the inversion control signal INVSL in the pattern program is set in the set register 20 prior to the start of the particular test item. For example, one of the code data corresponding to the non-inversion mode FP0, the checker board inversion mode FP1, the diagonal inversion mode FP2, the inverted diagonal inversion mode FP3 is set in the set register 20. The output signal from the set register 20 is supplied to an input terminal B of the first multiplexer (MUX) 30. The inversion mode set data in the set register 20 can be changed by the main program.

The mode select register 22 is a register for designating either one the traditional operation modes or the new operation mode. The mode (traditional or new operation mode) in the mode select register 22 can be change at any time through the tester bus TBUS. The output signal from the mode select register 22 is supplied to a selection control signal input terminal S of the second multiplexer 40.

The non-inversion detection circuit 34 receives the inversion control signal INVSL from the instruction memory WCS. When the non-inversion mode FP0 indicating a non-inversion condition, or “0”, for example, is detected, then the non-insertion detection circuit 34 provides a non-inversion detection signal 34s to the selection control signal input terminal S of the first multiplexer 30.

The first multiplexer 30 is a two input-one output selector, where an input terminal A receives an input corresponding to the non-inversion mode FP0, or “0”, for example, and the input terminal B receives, as noted above, the inversion mode set data 20s. The non-inversion signal “0” is output when the non-inversion detection signal 34s is valid, and the inversion mode set data 20s is output when the non-inversion detection signal 34s is invalid. The output of the first multiplexer 30 is then supplied to an input terminal A of the second multiplexer 40 as an inversion mode signal 30s.

According to this arrangement, when the inversion control signal INVSL from the instruction memory WCS is FP0, i.e., in the non-inversion mode, the non-inversion signal FP0 (“0”), is provided to the second multiplexer 40. When the inversion control signal INVSL is either FP1, FP2, or FP3, the inversion mode set data 20s is provided to the second multiplexer 40.

The second multiplexer 40 is a two input-one output selector with, for example, a 2-bit width, and can switch to either the traditional operation modes or the new operation mode. In other words, the input terminal A receives the above inversion mode signal 30s (new operation mode), and the input terminal B receives the inversion control signal INVSL (traditional operation mode) from the instruction memory WCS. Then, based on the operation mode from the mode selection register 22, the inversion control signal INVSL is output in the case of the traditional operation mode, and the inversion mode signal 30s is output in the case of the new operation mode. The output of the second multiplexer, i.e., the inversion control signal 40s is supplied to the inversion signal generator 60.

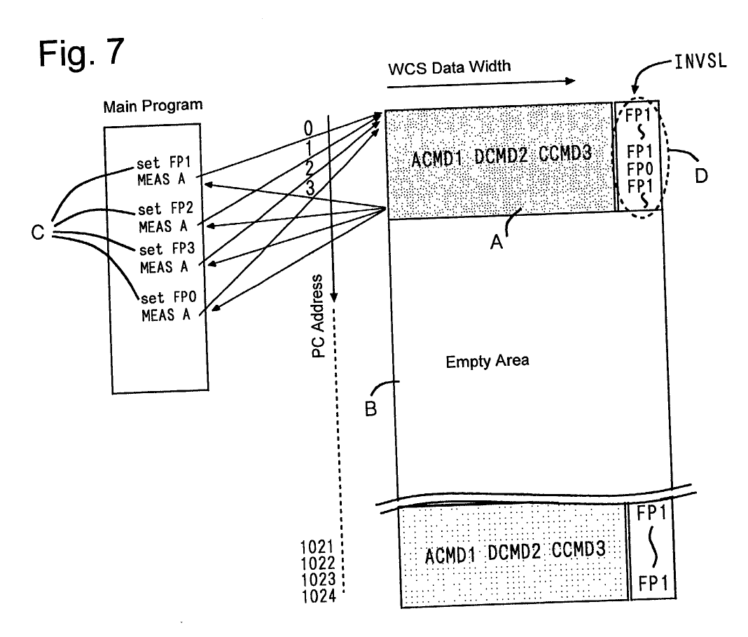

FIG. 7 shows an operational relationship between the main program and the pattern program, i.e., a manner of storing the pattern program from the main program in the instruction memory. Here, in the memory area D in FIG. 7 for storing the description concerning the inversion control signal INVSL, the non-inversion signal FP0 is described in the pattern line which is not involved with the inversion operation, and an intended inversion signal FP1, FP2, or FP3 is described in the pattern line which is involved with the inversion operation.

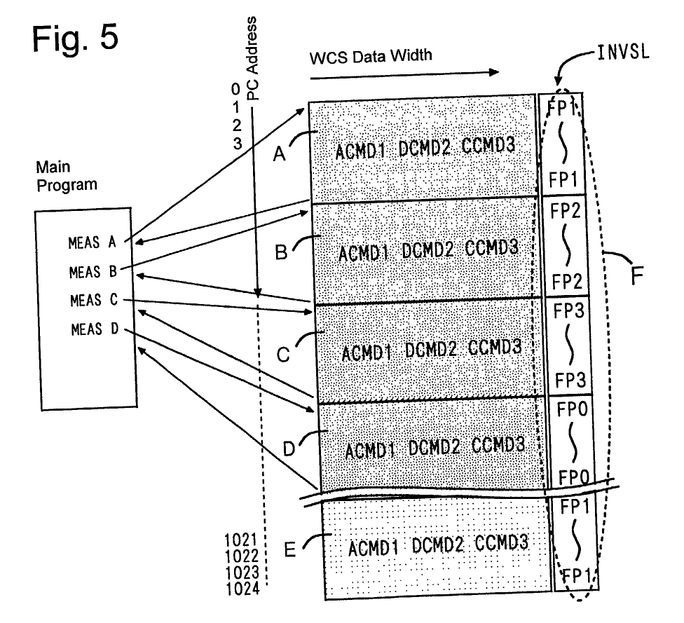

The main program is executed sequentially from the top to the bottom of FIG. 7. First, in the first “set FP1” line, the checker board inversion mode FP1 is set in the set register 20 through the tester bus TBUS. Then, the pattern program “ACMD1 DCMD2 CCMD3”, which is common to other test items as shown in FIG. 5, is called at the line “MEAS A” and stored in the instruction memory WCS as shown in the memory area A in FIG. 7 and is executed for performing the intended test item. After executing the pattern program “ACMD1 DCMD2 CCMD3”, the process returns to the main program. As a result, the test pattern has been generated based on the pattern program “ACMD1 DCMD2 CCMD3” which is inverted by the checker board inversion mode FP1.

In the “set FP2” line of the main program, the diagonal inversion mode FP2 is set in the set register 20 through the tester bus TBUS. Then, the pattern program “ACMD1 DCMD2 CCMD3” is called at the line “MEAS A” and stored in the instruction memory WCS as shown in the memory area A and is executed for performing the intended test item. After executing the pattern program “ACMD1 DCMD2 CCMD3”, the process returns to the main program. As a result, the test pattern has been generated based on the pattern program “ACMD1 DCMD2 CCMD3” which is inverted by the diagonal inversion mode FP2.

In the “set FP3” line of the main program, the inverted diagonal inversion mode FP3 is set in the set register 20 through the tester bus TBUS. Then, the pattern program “ACMD1 DCMD2 CCMD3” is called at the line “MEAS A” and stored in the instruction memory WCS as shown in the memory area A and is executed for performing the intended test item. After executing the pattern program “ACMD1 DCMD2 CCMD3”, the process returns to the main program. As a result, the test pattern has been generated based on the pattern program “ACMD1 DCMD2 CCMD3” which is inverted by the inverted diagonal inversion mode FP3.

Lastly, in the “set FP0” line of the main program, the non-inversion mode FP0 is set in the set register 20 through the tester bus TBUS. Then, the pattern program “ACMD1 DCMD2 CCMD3” is called at the line “MEAS A” and stored in the instruction memory WCS as shown in the memory area A and is executed for performing the intended test item. After executing the pattern program “ACMD1 DCMD2 CCMD3”, the process returns to the main program. Thus, the test pattern has been generated based on the pattern program “ACMD1 DCMD2 CCMD3” which not inverted because of the non-inversion mode FP0.

Therefore, according to the above mentioned structure, the inversion control signal INVSL from the instruction memory WCS is received by the inversion control switch circuit 80 and is switched to the predetermined mode and is supplied to the inversion signal generator 60. As a result, the designation of one of the inversion modes FP1-FP3 described in the pattern programs do not have to be dependent on in the new operation mode, making it possible to be replaced with the modes FP0-FP3 that have been set in the set register 20. Accordingly, in the above example, the same pattern program can be repeatedly used for four different test items with use of only the memory area A in the instruction memory WCS.

Further, because the present invention requires a substantially smaller memory capacity in the instruction memory WCS than that required in the conventional technology, it becomes unnecessary to divide the pattern program to be loaded in the instruction memory WCS even when testing a complicated memory device.

The concept of the present invention is not limited to the specific structures or circuit connections in the embodiment described above. The basic concept of the present invention can be applied to various other structures and circuit connections or different modes.

For example, the foregoing embodiment includes only three types of inversion modes, however, in an actual semiconductor test system, an actual inversion signal generator involves a larger number of inversion modes, such as ten or more. In such a situation, as a result of being able to use the common pattern program for different inversion modes, such as ten different modes, with use of only one memory area for the pattern program, further reduction of the memory, such as 1/10 compared to the conventional technology can be achieved in the instruction memory. Further, the number of inversion modes may possibly increase in the future, however, according to the present invention, such an increase in the number and type of inversion modes will not affect the required storage capacity in the instruction memory.

Furthermore, the foregoing example includes the mode select register 22 and the second multiplexer 40 for switching between the traditional operation mode and the new operation mode. However, in the case where a plurality of pattern programs in the traditional operation mode are reduced to one common pattern program, the mode select register 22 and the second multiplexer 40 can be removed from the inversion control switch circuit 80.

Further, the foregoing example is directed to the case where the inversion control signal INVSL from the instruction memory is controlled in a manner to reduce the memory areas for storing the pattern program involved in the inversion operation. However, the present invention is also applicable to other situations where a pattern program is commonly used in different test items.

According to the present invention as explained above, the pattern components (such as the inversion control signals INVSL, and inversion modes FP1-FP3) associated with the common pattern program are separated from that pattern program and are freely specified and called (ex., in the set register 20), and are freely assigned to the pattern program through the specific circuit arrangement (ex., the inversion control switch circuit 80 and the inversion signal generator 60). Therefore, it is possible to commonly utilize the same pattern program for different test items, thereby enabling to decrease the required capacity in the instruction memory in the pattern generator. Especially, the generation of various inversion data such as the checker board, diagonal, and inverted diagonal can be made by using the same pattern program without increasing the memory capacity.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. A semiconductor test system for testing semiconductor devices by applying a test pattern to a semiconductor device under test, comprising:
means for storing a main program for controlling an overall operation of the semiconductor test system, the main program including pattern programs for producing test patterns to be applied to a device under test;
an instruction memory for storing a pattern program and control mode data from the main program required for generating a test pattern for conducting an intended test item on the device under test;
means for generating a data pattern which is a part of the test pattern to be applied to the device under test and modifying the data pattern;
means for setting control mode data identical to that stored in the instruction memory in a temporary storage;
means for producing a modification signal based on the control mode data and providing the modification signal to the data pattern generating means to modify the data pattern; and
means for switching the control mode data either from the instruction memory or from the temporary storage for producing a selection control signal for controlling the modification signal producing means in generating the modification signal.

2. A semiconductor test system as defined in claim 1, wherein said temporary storage in said control mode data setting means is a register which receives said control mode data from the main program.

3. A semiconductor test system as defined in claim 1, wherein said switching means includes a mode selection register which specifies either a first mode or a second mode wherein, in the first mode, said modification signal producing means is controlled based on the control mode data from the instruction memory, and in the second mode, said modification signal producing means is controlled based on the control mode data from the temporary storage.

4. A semiconductor test system as defined in claim 1, wherein said modification signal from the modification signal producing means is a signal indicating an inversion operation and is applied to a data inversion circuit for inverting the data from the data pattern generating means.

5. A semiconductor test system as defined in claim 1, wherein said modification signal producing means includes one or more inversion signal generators each generating an inversion signal based on a predetermined inversion algorithm, and a selector for selecting an inversion signal from one of the inversion signal generators to be used as said modification signal in response to said control mode data from either the instruction memory or from the temporary storage.

6. A semiconductor test system as defined in claim 5, wherein said inversion algorithm includes a checker board inversion algorithm, a diagonal inversion algorithm, and an inverted diagonal algorithm wherein each algorithm by the inversion signal generator is performed with use of address data supplied to the semiconductor device under test.

7. A semiconductor test system for testing semiconductor devices by applying a test pattern to a semiconductor device under test, comprising:
a main program for controlling an overall operation of the semiconductor test system, the main program including pattern programs for producing test patterns to be applied to a device under test;
an instruction memory for storing a pattern program and control mode data from the main program required for generating a test pattern for conducting an intended test item on the device under test;
a data pattern generator for generating data pattern which is a part of the test pattern to be applied to the device under test and modifying the data pattern;
a temporary storage for indicating control mode data from the main program identical to that stored in the instruction memory;
a modification signal generator for generating a modification signal based on the control mode data and providing the modification signal to the data pattern generator to modify the data pattern; and
a control mode switch circuit for selecting the control mode data either from the instruction memory or from the temporary storage for producing a selection control signal for controlling the modification signal generator in generating the modification signal.

8. A semiconductor test system as defined in claim 7, wherein said temporary storage is a register which receives said control mode data from the main program.

9. A semiconductor test system as defined in claim 7, wherein said control mode switch circuit includes a mode selection register which specifies either a first mode or a second mode wherein, in the first mode, said modification signal generator is controlled based on the control mode data from the instruction memory, and in the second mode, said modification signal generator is controlled based on the control mode data from the temporary storage.

10. A semiconductor test system as defined in claim 7, wherein said modification signal from the modification signal generator is a signal indicating an inversion operation and is applied to a data inversion circuit for inverting the data from the data pattern generator.

11. A semiconductor test system as defined in claim 7, wherein said modification signal generator includes one or more inversion signal generators each generating an inversion signal based on a predetermined inversion algorithm, and a selector for selecting an inversion signal from one of the inversion signal generators to be used as said modification signal in response to said control mode data from either the instruction memory or from the temporary storage.

12. A semiconductor test system as defined in claim 11, wherein said inversion algorithm includes a checker board inversion algorithm, a diagonal inversion algorithm, and an inverted diagonal algorithm wherein each algorithm by the inversion signal generator is performed with use of address data supplied to the semiconductor device under test.

13. A semiconductor test system for testing semiconductor devices by applying a test pattern to a semiconductor device under test, comprising:
a main program for controlling an overall operation of the semiconductor test system, the main program including pattern programs for producing test patterns to be applied to a semiconductor device under test;
a tester bus for interfacing data in the semiconductor test system;
an algorithmic pattern generator for generating a test pattern with sequence based on a predetermined algorithm for testing the semiconductor device; said algorithmic pattern generator comprising:
an address generator for generating an address pattern which is a part of the test pattern applied to the semiconductor device under test;
a data generator for generating a data pattern which is a part of the test pattern to be applied to the device under test and modifying the data pattern based on the predetermined algorithm;
a sequence controller for providing instructions to the address generator and the data generator, said sequence controller including an instruction memory for storing a pattern program and control mode data from the main program required for generating a test pattern for conducting an intended test item on the semiconductor device under test;
a temporary storage for indicating control mode data from the main program through the tester bus wherein the control mode data is identical to that stored in the instruction memory;
a modification signal generator for generating a modification signal based on the control mode data and providing the modification signal to the data generator to modify the data pattern; and
a control mode switch circuit for selecting the control mode data either from the instruction memory or from the temporary storage for producing a selection control signal for controlling the modification signal generator in generating the modification signal.

14. A semiconductor test system as defined in claim 13, wherein said temporary storage is a register which receives said control mode data from the main program through the tester bus.

15. A semiconductor test system as defined in claim 13, wherein said control mode switch circuit includes a mode selection register which specifies either a first mode or a second mode wherein, in the first mode, said modification signal generator is controlled based on the control mode data from the instruction memory, and in the second mode, said modification signal generator is controlled based on the control mode data from the temporary storage.

16. A semiconductor test system as defined in claim 13, wherein said modification signal from the modification signal generator is a signal indicating an inversion operation and is applied to a data inversion circuit for inverting the data from the data generator.

17. A semiconductor test system as defined in claim 13, wherein said modification signal generator includes one or more inversion signal generators each generating an inversion signal based on a predetermined inversion algorithm with use of the address pattern from the address generator, and a selector for selecting an inversion signal from one of the inversion signal generators to be used as said modification signal in response to said control mode data from either the instruction memory or from the temporary storage.

18. A semiconductor test system as defined in claim 17, wherein said inversion algorithm includes a checker board inversion algorithm, a diagonal inversion algorithm, and an inverted diagonal algorithm wherein each algorithm by the inversion signal generator is performed with use of address pattern from the address generator.
